(19) United States
(12) Patent Application Publication
(10) Pub. No.: US 2006/0066381 A1
(43) Pub. Date: Mar. 30, 2006

(54) Voltage level translator circuit with feedback

(76) Inventors: Dipankar Bhattacharya, Macungie, PA (US); John C. Kriz, Palmerton, PA (US); Brian C. Lacey, Kunkletown, PA (US); Bruce W. McNeill, Allentown, PA (US); Bernard L. Morris, Emmaus, PA (US)

Correspondence Address: Ryan, Mason & Lewis, LLP, 90 Forest Avenue, Locust Valley, NY, 11560, US

(21) Appl. No.: 10/956,000

(22) Filed: Sep. 30, 2004

(51) Int. Cl. H03L 5/00

(52) U.S. Cl. 327/333

(57) ABSTRACT

A voltage level translator circuit for translating an input signal referenced to a first voltage supply to an output signal referenced to a second voltage supply includes an input stage for receiving the input signal and a latch circuit for storing a signal at an output of the latch circuit which is representative of a logical state of the input signal. The latch circuit includes an input coupled to the input stage. The voltage level translator circuit further includes a feedback circuit coupled between the input and the output of the latch circuit. The feedback circuit is operative to maintain a desired logic state of the voltage level translator circuit when the second voltage supply powers up before the first voltage supply. In this manner, the voltage level translator circuit is configured to provide an output signal having a predictable logic state over a wide variation of PVT conditions and/or voltage supply ramp rates.

### FIELD OF THE INVENTION

The present invention relates generally to electronic circuits, and more particularly relates to voltage level translator circuits.

### BACKGROUND OF THE INVENTION

Certain portable devices, including wireless handsets, notebook computers and personal digital assistants (PDAs), often employ circuitry which runs on two or more different voltage levels. For instance, circuitry utilized with such portable devices may be configured so that a portion of the circuitry, such as, for example, input/output (IO) buffers, runs at a higher voltage level (e.g., about 3.3 volts), while another portion of the circuitry, such as, for example, core logic, runs at a substantially lower voltage level (e.g., about 1.0 volt). This difference in voltage levels often necessitates the use of a voltage level translator circuit for interfacing between the multiple voltage levels.

One known technique for interfacing between the multiple voltage levels is illustrated in the standard voltage level translator circuit 100 shown in FIG. 1. The circuit 100 employs two types of transistors, namely, “high voltage” transistors, which are intended to operate with a higher supply voltage VDDIO (e.g., about 3.3 volts), and “low voltage” transistors, which are intended to operate with a lower core supply voltage VDDCORE (e.g., about 1.0 volt). The low voltage devices have a nominal threshold voltage which is substantially lower than that of the high voltage devices. Traditional mixed signal integrated circuit processes typically offer both high voltage and low voltage transistor devices. In the voltage level translator circuit 100, transistor devices M3PA, M3PB, M3PC, M3NA, M3NB and M3NC are high voltage devices for use with the higher voltage supply, while transistors M1PA and M1NA are low voltage devices for use with the lower voltage supply. The transistors M1PA and M1NA are configured as a standard inverter 102 for generating a signal AN at node NO which is a complement of signal A. Signals A and AN are core logic signals referenced with respect to the lower core supply VDDCORE.

The voltage level translator circuit 100 is configured such that source terminals (S) of transistors M3PA and M3PB are connected to VDDIO, a gate terminal (G) of M3PB is connected to a drain terminal (D) of M3PA at node N1, and a gate terminal of M3PA is connected to a drain terminal of M3PB at node N2. Drain terminals of transistors M3NA and M3NB are connected to the drain terminals of M3PA and M3PB at nodes N1 and N2, respectively. Source terminals of transistors M3NA and M3NB are connected to negative voltage supply VSS of the circuit 100. A gate terminal of transistor M3NA receives the core logic signal A to be translated, and a gate terminal of transistor M3NB receives the core logic signal AN. Transistors M3PC and M3NC are configured as an inverter 104 having an input connected to node N1 and generating an output signal Z at node N3, which forms an output of the circuit 100.

Under nominal circuit operation, when signal A is a logic high (e.g., VDDCORE), transistor M3NA is turned on, thereby pulling node N1 to VSS. Signal AN will be a logic low (e.g., VSS), thereby turning transistor M3NB off. Since node N1 is low, transistor M3PB will be turned on, thereby pulling node N2 to VDDIO and turning off device M3PA. This half-latch structure is stable and output signal Z will be a logic high, referenced with respect to VDDIO. Similarly, when signal A is a logic low, transistor M3NA will be turned off. Signal AN will be a logic high, thus turning on transistor M3NB and pulling node N2 to VSS. Node N2 being a logic low turns on transistor M3PA, thereby pulling node N1 to VDDIO. Output signal Z will therefore be a logic low. In this manner, the circuit 100 translates an input signal (e.g., signal A) referenced to the lower core voltage supply VDDCORE to an output signal (e.g., signal Z) referenced to the higher voltage supply VDDIO.

A primary disadvantage with this conventional approach, however, is that when the core supply VDDCORE is off and/or powering up while the higher supply VDDIO is on, as will be the case, for example, when the higher supply VDDIO ramps up before the core supply VDDCORE from a power-up reset (PUR) state, node N1 may be undefined. Since devices M3NA and M3NB are both turned off in this instance, node N1 may float to some intermediate voltage level, thereby providing a direct current (DC) path from VDDIO to VSS, through devices M3PC and M3NC in inverter 104, through which a significant current may flow. Moreover, node N1 may float to either one of the voltage supply rails, namely, VDDIO or VSS, thereby generating an output signal Z having either a logic low or a logic high state, respectively, at node N3. In either case, the logic state of the output signal Z may be indeterminate or erroneous, particularly over certain process, voltage and/or temperature (PVT) variations and/or variations in supply voltage ramp rates.

There exists a need, therefore, for an improved voltage level translator circuit for interfacing between multiple voltage levels that does not suffer from one or more of the problems exhibited by conventional voltage level translator circuits.

### SUMMARY OF THE INVENTION

The present invention meets the above-noted need by providing, in an illustrative embodiment, a voltage translator circuit capable of interfacing between multiple voltage levels, such as, for example, between an input signal, which is referenced to a lower core voltage supply of the circuit, and an output signal, which is referenced to a higher voltage supply of the circuit. The voltage translator circuit is advantageously configured to generate an output signal having a predictable logic state, particularly when the higher voltage supply powers up before the lower core voltage supply, without consuming any significant DC power. Moreover, the voltage level translator circuit is configured to provide a predictable logic output over a wide variation of PVT conditions and/or voltage supply ramp rates.

In accordance with one aspect of the invention, a voltage level translator circuit for translating an input signal referenced to a first voltage supply to an output signal referenced to a second voltage supply includes an input stage for receiving the input signal and a latch circuit for storing a signal at an output of the latch circuit which is representative of a logical state of the input signal. The latch circuit includes an input coupled to the input stage. The voltage level translator circuit further includes a feedback circuit coupled between the input and the output of the latch circuit. The feedback circuit is operative to maintain a desired logic state of the voltage level translator circuit when the second voltage supply powers up before the first voltage supply.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is a schematic diagram illustrating a conventional voltage level translator circuit.

FIG. 2 is a schematic diagram depicting a voltage level translator circuit in which the methodologies of the present invention may be implemented.

FIG. 3 is a schematic diagram illustrating an exemplary voltage level translator circuit, formed in accordance with one embodiment of the present invention.

FIG. 4 is a schematic diagram illustrating an exemplary voltage level translator circuit, formed in accordance with a second embodiment of the present invention.

FIG. 5 is a schematic diagram illustrating an exemplary voltage level translator circuit, formed in accordance with a third embodiment of the present invention.

### DETAILED DESCRIPTION OF THE INVENTION

The present invention will be described herein in the context of illustrative voltage level translator circuits. It should be understood, however, that the present invention is not limited to these or any other particular circuit arrangements. Rather, the invention is more generally applicable to improved techniques for interfacing between multiple voltage levels in a circuit without consuming any significant DC power. Furthermore, the techniques of the present invention may be used to set an output signal generated by the voltage level translator circuit to a known logic state, particularly when a higher voltage supply, to which the output signal of the circuit is referenced, powers up before a lower core supply, to which an input signal to the circuit is referenced. Although implementations of the present invention are described herein with specific reference to P-type metal-oxide-semiconductor (PMOS) and N-type metal-oxide-semiconductor (NMOS) transistor devices, as may be formed using a complementary metal-oxide-semiconductor (CMOS) fabrication process, it is to be appreciated that the invention is not limited to such transistor devices and/or such a fabrication process, and that other suitable devices, such as, for example, bipolar junction transistors (BJTs), etc., and/or fabrication processes (e.g., bipolar, BiCMOS, etc.), may be similarly employed, as will be understood by those skilled in the art.

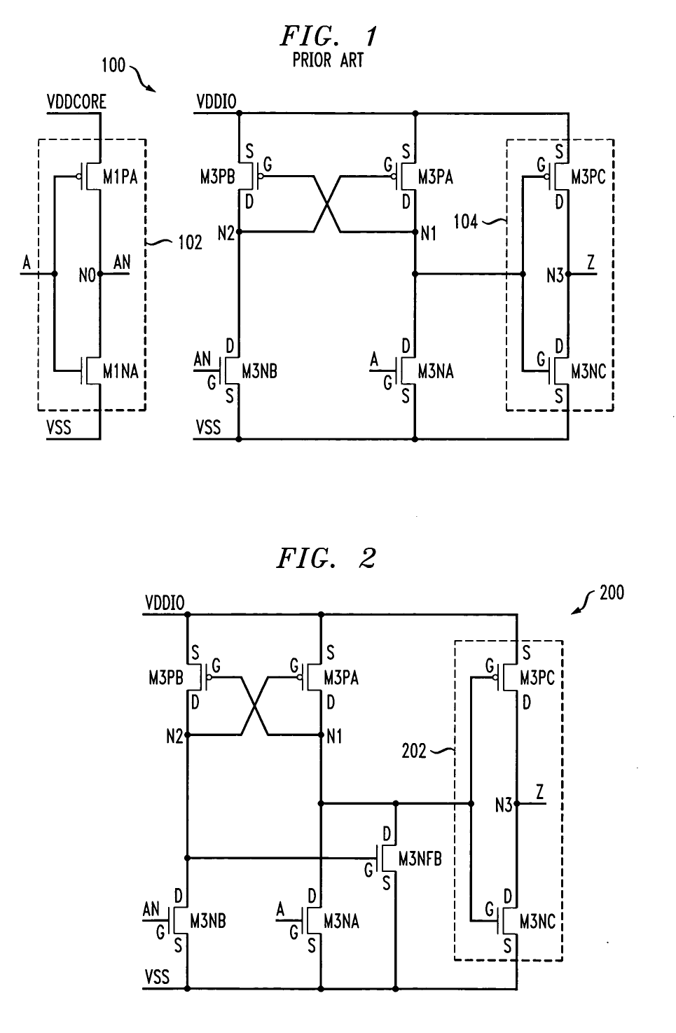

FIG. 2 illustrates a voltage level translator circuit 200 in which the techniques of the present invention can be implemented. The voltage level translator circuit 200 can be used to translate input signals (e.g., signals A and AN) referenced to a lower core supply voltage, such as, for example, VDDCORE, to an output signal Z which is referenced to a higher supply voltage, such as, for example, VDDIO. In many applications, the lower core supply voltage VDDCORE is typically about 1.0 volt and the higher supply voltage VDDIO is typically about 3.3 volts. It is to be appreciated, however, that the present invention is not limited to these or to any other particular voltage levels for VDDCORE and VDDIO. Furthermore, the techniques of the present invention may be similarly employed to translate an input signal referenced to the higher supply voltage VDDIO to an output signal referenced to the lower core supply voltage VDDCORE, as will be understood by those skilled in the art.

The illustrative voltage level translator circuit 200 includes PMOS transistors M3PA, M3PB and M3PC, and NMOS transistors M3NA, M3NB, M3NC and M3NFB. Each of the transistors included in the voltage level translator circuit 200 are preferably “high voltage” transistors. Transistors forming core logic circuitry used to generate the input signals A and AN, such as, for example, inverter 102 shown in FIG. 1, are preferably “low voltage” transistors. As previously stated, traditional mixed signal integrated circuit processes typically offer both high voltage and low voltage transistor devices. The high voltage devices generally have a nominal threshold voltage of about 0.75 volts and are intended to operate with the higher supply voltage VDDIO (e.g., about 3.3 volts). The low voltage devices have a nominal threshold voltage which is substantially lower than the high voltage devices, such as, for example, about 0.35 volts, and are intended to operate with the lower core supply voltage VDDCORE (e.g., about 1.0 volt).

Like the voltage level translator circuit 100 depicted in FIG. 1, voltage level translator circuit 200 comprises a pair of PMOS transistors M3PA and M3PB each having a source terminal connected to the positive voltage supply VDDIO, and having a gate terminal of one transistor connected to a drain terminal of the other transistor in a cross-coupled arrangement. Specifically, the gate terminal of M3PA is connected to the drain terminal of M3PB at node N2, and the gate terminal of M3PB is connected to the drain terminal of M3PA at node N1. It is to be appreciated that, because the MOS device is symmetrical in nature, and thus bidirectional, the assignment of source and drain designations in the MOS device is essentially arbitrary. Therefore, the source and drain terminals may be referred to generally as first and second source/drain terminals, respectively, where “source/drain” in this context denotes a source terminal or a drain terminal.

The voltage level translator circuit 200 further comprises NMOS transistor M3NA having a source terminal connected to a reference supply, which may be VSS, a drain terminal connected to node N1, and a gate terminal for receiving input signal A. Voltage level translator circuit 200 also includes NMOS transistor M3NB having a source terminal connected to the reference supply VSS, a drain terminal connected to node N2, and a gate terminal for receiving input signal AN. An output stage comprising PMOS transistor M3PC and NMOS transistor M3NC connected togther as a standard inverter 202, is connected to node N1 and generates the output signal Z of the voltage level translator circuit 200.

Under most operating conditions of the circuit 200, signal A being a logic high (“1”) turns on transistor M3NA, pulling node N1 low. Signal AN being an inversion of signal A will thus be a logic low (“0”), thereby turning off transistor M3NB. Node N1 being at a low voltage turns on transistor M3PB, pulling node N2 high and turning off transistor M3PA. The output signal Z being an inversion of node N1 will be a logic high when node N1 is low. However, as previously explained, in certain instances, such as, for example, when the higher voltage supply VDDIO powers up before the lower core voltage supply VDDCORE, node N1 may float to some intermediate voltage level, thereby causing the circuit 200 to consume significant DC current, primarily through an electrical path established between VDDIO and VSS via transistors M3PC and M3NC. Alternatively, if the voltage at node N1 floats to one of the voltage supply rails (e.g., VDDIO ro VSS), the output signal Z generated by circuit 200 may produce an erroneous logic state. In either case, however, the logical state of the output signal Z is indeterminate.

In order to reduce the likelihood that node N1 will float to some intermediate voltage level when VDDIO powers up before the core voltage supply VDDCORE, the voltage level translator circuit 200 may include NMOS transistor M3NFB operative to feed back an inversion of the voltage at node N2 to node N1. Consequently, transistor M3NFB may be referred to herein as a feedback device. Specifically, a drain terminal of transistor M3NFB is connected to node N1 and a source terminal of M3NFB is connected to VSS. A gate terminal of M3NFB is connected to node N2. For most process, voltage, and/or temperature (PVT) conditions and/or for a slow VDDIO ramp rate relative to a ramp rate of the core supply VDDCORE, node N2 will be a logic high, thereby turning on transistor M3NFB and pulling node N1 to VSS. Node N1 being a logic low forces the output signal Z to a high logic state. However, under certain PVT conditions and/or for a fast VDDIO ramp rate relative to the ramp rate of VDDCORE, node N2 may be a logic low turning on transistor M3PA and pulling node N1 high, thereby forcing the output signal Z to a low logic state. Thus, while transistor M3NFB may reduce the likelihood that node N1 will float to an intermediate voltage level, thereby causing the voltage level translator circuit 200 to consume excessive current, the circuit 200 does not provide an output signal Z having a predictable logic state for substantially all PVT conditions and/or VDDIO ramp rates.

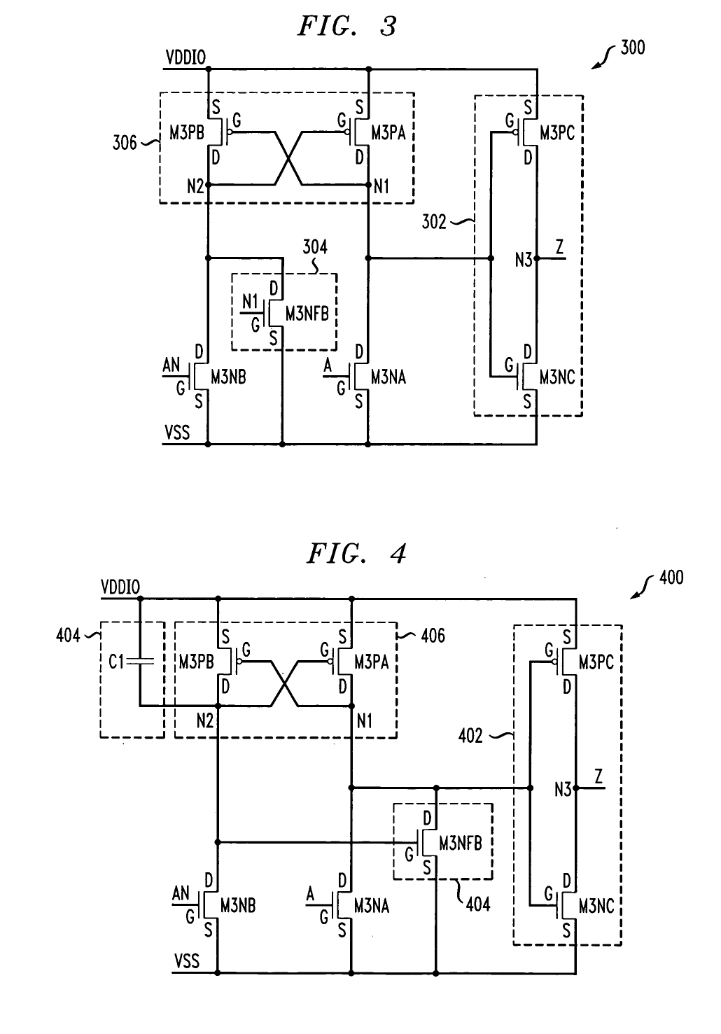

FIG. 3 depicts an exemplary voltage level translator circuit 300, formed in accordance with an illustrative embodiment of the present invention. The exemplary voltage level translator circuit 300 includes a latch circuit 306 for storing a signal at node N1 which is representative of a logical state of an input signal A or AN presented to the circuit. Because latch circuit 306 includes two nodes, namely, node N1 and N2, the latch circuit may be referred to as a differential latch. The input signals A and AN are referenced with respect to a different voltage supply, such as, for example, a core voltage supply VDDCORE, compared to a voltage supply used to power the circuit 300, such as, for example, voltage supply VDDIO. The latch circuit 306 preferably comprises PMOS transistors M3PA and M3PB connected in a cross-coupled arrangement. Specifically, source terminals of transistors M3PA and M3PB are connected to voltage supply VDDIO, a drain terminal of M3PA is connected to a gate terminal of M3PB at node N1, and a drain terminal of M3PB is connected to a gate terminal of M3PA at node N2. All of the transistor devices in circuit 300 are preferably high voltage devices.

An input stage comprising NMOS transistors M3NA and M3NB is preferably coupled to the latch circuit 306. Specifically, source terminals of transistors M3NA and M3NB are connected to a reference voltage supply, which may be VSS, and drain terminals of M3NA and M3NB are coupled to the latch circuit 306 at nodes N1 and N2, respectively. A gate terminal of M3NA preferably receives input signal A, which, as stated above, is referenced to the lower core voltage supply VDDCORE. A gate terminal of M3NB receives input signal AN, which is a logical inversion of input signal A and is similarly referenced to the core voltage supply VDDCORE. Transistors M3NA and M3NB function, at least in part, as pull-down load devices for the latch circuit 306. The respective sizes of M3NA and M3NB are preferably selected so as to provide sufficient overdrive for pulling down nodes N1 and N2, respectively, under worst case PVT conditions, such as, for example, when VDDCORE is at a minimum defined voltage limit (e.g., 0.9 volt) and/or a threshold voltage of high voltage transistor devices M3NA and M3NB are at a maximum defined voltage limit (e.g., 0.85 volt).

The voltage level translator circuit 300 may also include an output stage 302 for buffering the output signal stored in the latch circuit 306 and for generating a buffered output signal (e.g., signal Z) of the voltage level translator circuit having substantially rail-to-rail (e.g., VSS to VDDIO) logic levels. Output stage 302 is preferably configured so as to provide an output signal Z which has a logic state that corresponds to the logic state of the input signal A, although such a correspondence between the output signal and the input signal is not a requirement of the invention. Thus, it is to be understood that while output stage 302 is shown as generating an output signal Z that is an inversion of the signal at node N1, the output stage need not provide an inversion function.

The output stage 302 preferably has an input coupled to node N1 and an output at node N3 for generating the output signal Z based on at least one of the input signals A and AN. The output stage 302 comprises a PMOS transistor M3PC and an NMOS transistor M3NC configured as a standard inverter, although alternative circuit configurations are similarly contemplated by the invention. Specifically, a source terminal of M3PC is connected to VDDIO, a source terminal of M3NC is connected to VSS. Gate terminals of transistors M3PC and M3NC are connected together to form the input of stage 302 at node N1, and drain terminals of M3PC and M3NC are connected together to form the output of the voltage level translator circuit 300 at node N3.

Observing the exemplary voltage level translator circuit 300 it becomes evident that node N1 has a greater coupling capacitance to the voltage supply VDDIO than node N2. This is due primarily to the fact that node N1 drives the output stage 302, which, in this instance, comprises a standard inverter. A gate-to-source overlap capacitance associated with transistor M3PC of the output stage 302 contributes significantly to the overall coupling capacitance from node N1 to VDDIO. Therefore, when VDDIO ramps up, node N1 which is coupled to VDDIO follows accordingly, thereby turning off transistor M3PB and allowing node N2 to float.

In accordance with one aspect of the invention, in order to set node N2 to a known logic state for substantially all PVT conditions and/or VDDIO ramp rates, a feedback circuit 304 is coupled to node N2. The feedback circuit 304 is operative to feed back a voltage to node N2 which is a function of the voltage at node N1. In the exemplary voltage level translator circuit 300, feedback circuit 304 is configured to feed back an inversion of the voltage present at node N1 to node N2. Although feedback circuit 304 is not limited to any particular circuit arrangement, the feedback circuit preferably comprises a high voltage NMOS transistor M3NFB having a drain terminal connected to node N2 and a source terminal connected to VSS, or an alternative reference voltage source. A gate terminal of transistor M3NFB is preferably coupled to node N1, and is therefore controlled by the voltage appearing at node N1. It is to be appreciated that an alternative control signal may be similarly applied to the gate terminal of M3NFB for controlling the voltage at node N2. Transistor M3NFB should be sized appropriately so as to provide sufficient drive capability for pulling node N2 low, without adding significant capacitance to node N2.

By way of example only, the operation of voltage level translator circuit 300 will be described. It is assumed that the core voltage supply VDDCORE has not yet powered up, and therefore signals A and AN will both be a logic low, thereby turning off transistors M3NA and M3NB. Since node N1 will be more capacitively coupled to VDDIO than node N2 as a result of the output stage 302 connected to node N1, node N1 will tend to at least initially follow VDDIO as VDDIO ramps up. Once node N1 exceeds a threshold voltage (e.g., about 0.75 volts) above VSS, transistor M3NFB will turn on, thereby pulling node N2 low. Node N2 being low turns on transistor M3PA, thereby pulling node N1 even harder to VDDIO. This is a stable circuit configuration, wherein the output signal Z will be set to a logic low state for substantially all specified PVT conditions and/or VDDIO ramp rates. Moreover, the feedback circuit 304 does not consume any significant additional DC current (e.g., less than about one microampere). The logic state of the output signal Z may be changed as desired, for example, by inverting the signal presented to the output stage 302, such as by adding an inverter (not shown) between node N1 and the input of output stage 302.

Under normal operation of the voltage level translator circuit 300, such as, for example, when VDDIO and VDDCORE have reached their respective steady-state voltage levels, the feedback circuit 304 has essentially no adverse effect on the voltage level translation function of the circuit. For example, when signal A is a logic high, transistor M3NA will turn on, thereby pulling node N1 low and turning off transistor M3NFB. Node N1 being low forces output signal Z to a logic high. Node N1 being low also turns on transistor M3PB, thereby pulling node N2 high. Signal AN, being a complement of signal A, will be a logic low, thereby turning off transistor M3NB. With transistors M3NB and M3NFB being turned off, node N2 is allowed to be pulled high. Similarly, when signal A is low, transistor M3NA is turned off. Signal AN, being a complement of signal A, will be high, thereby turning on transistor M3NB and pulling node N2 low. Once node N2 falls about a threshold voltage below VDDIO, transistor M3PA turns on, thereby pulling node N1 high and turning off transistor M3PB. Node N1 being high turns on transistor M3NFB, thereby pulling node N2 low even harder. Thus in either case, feedback circuit 304 prevents node N1 from floating to an intermediate voltage level when the voltage supply VDDIO powers up before the core voltage supply VDDCORE, without consuming any significant DC current. Moreover, since node N1 will normally be of the same logic level as signal AN, transistor M3NB and M3NFB will essentially function as two devices in parallel with one another.

The feedback circuit 304 may also be advantageously employed for setting the output signal Z to a known logic state during other operating conditions of the voltage level translator circuit 400, such as, for example, when VDDCORE powers down after the output signal Z has already been defined. In this instance, input signals A and AN will each be a low logic state, which would otherwise allow node N1 to float to some intermediate voltage level. The latch circuit 306 in conjunction with feedback circuit 304 will maintain a low logic state of the output signal Z. A substantially static design approach is employed for the voltage level translator circuit 300 which advantageously provides robust logic functionality that consumes essentially no DC current, other than perhaps transistor leakage current, when inputs are quiescent.

FIG. 4 depicts an exemplary voltage level translator circuit 400, formed in accordance with another embodiment of the invention. In contrast to the voltage level translator circuit 300 of FIG. 3, which is configured to provide a predictable logic low output signal when VDDIO powers up before the core voltage supply VDDCORE, voltage level translator circuit 400 is preferably configured to provide a logic high output signal without consuming any significant DC current. Like the voltage level translator circuit 300 shown in FIG. 3, the exemplary voltage level translator circuit 400 includes a latch circuit 406 for storing a signal at node N1 which is representative of a logical state of an input signal A or AN presented to the circuit. The input signals A and AN are referenced with respect to a voltage supply (e.g., VDDCORE) that is different than the voltage supply (e.g., VDDIO) used to supply power to the circuit 400. Like the latch circuit 306 depicted in FIG. 3, latch circuit 406 preferably comprises high voltage PMOS transistors M3PA and M3PB connected in a cross-coupled arrangement. Specifically, source terminals of transistors M3PA and M3PB are connected to voltage supply VDDIO, a drain terminal of M3PA is connected to a gate terminal of M3PB at node N1, and a drain terminal of M3PB is connected to a gate terminal of M3PA at node N2.

The voltage level translator circuit 400 further includes an input stage coupled to the latch circuit 406 for receiving the input signals A and AN, signal AN being a complement of signal A. It is to be appreciated that in a single-ended mode of operation, that input stage may only receive one of the input signals A or AN. While the voltage level translator circuit 400 is not limited to a particular input stage, the input stage preferably comprises a pair of high voltage NMOS transistors M3NA and M3NB having source terminals connected to a reference voltage supply, which may be VSS, and having drain terminals coupled to corresponding nodes N1 and N2, respectively, of the latch circuit 406. Gate terminals of transistors M3NA and M3NB preferably receive the input signals A and AN, respectively. The respective sizes of M3NA and M3NB are preferably chosen so as to provide sufficient overdrive capability under substantially all expected worst case PVT corners of the circuit 400.

An output stage 402 may be coupled to node N1 for buffering the output signal stored in the latch circuit 406 and for generating a buffered output signal (e.g., signal Z) of the voltage level translator circuit 400 having substantially rail-to-rail (e.g., VSS to VDDIO) logic levels. The output stage 402 preferably has an input coupled to node N1 and an output at node N3 for generating the output signal Z based on at least one of the input signals A and AN. The output stage 402 comprises a high voltage PMOS transistor M3PC and a high voltage NMOS transistor M3NC configured as a standard inverter, although alternative circuit configurations are similarly contemplated. The output stage 402 preferably provides an output signal Z having a logic state which corresponds to a logic state of the input signal A.

In order to set the output signal Z of the voltage level translator circuit 400 to a known logic state, particularly when the voltage supply VDDIO is ramping up, the circuit preferably includes a feedback circuit 404. The feedback circuit 404 preferably comprises a high voltage NMOS transistor M3NFB having a drain terminal connected to node N1, a source terminal connected to a reference voltage (e.g., VSS), and a gate terminal connected to node N2. The voltage at node N2 serves as a control signal for controlling transistor M3NFB, such that when node N2 is above a threshold voltage of M3NFB, M3NFB turns on, thereby pulling node N1 low.

For most PVT conditions and/or for a slow VDDIO ramp rate relative to a ramp rate of VDDCORE, node N2 will be a logic high, thereby turning on transistor M3NFB and pulling node N1 low. This is a stable circuit configuration, wherein node N1 being low forces the output signal Z to a high logic state. However, a coupling capacitance between node N1 and VDDIO is higher compared to a coupling capacitance between node N2 and VDDIO, due at least in part to the presence of output stage 402 connected to node N1. Consequently, under certain PVT conditions and/or for a fast VDDIO ramp rate relative to the ramp rate of VDDCORE, node N1 may be high and node N2 may be low, turning off transistor M3NFB. Node N2 being low turns on transistor M3PA, thereby pulling node N1 high even harder and forcing the output signal Z to a low logic state. This is also a stable circuit configuration. Thus, without a slight modification, as will be described below, the voltage level translator circuit 400, like the circuit 200 shown in FIG. 2, does not provide an output signal Z having a sufficiently predictable logic state.

In order to beneficially provide an output signal Z having a predictable logic state for substantially all specified PVT conditions and/or VDDIO ramp rates, the feedback circuit 404 preferably further comprises a capacitor C1, or an alternative capacitance device (e.g., an NMOS or PMOS transistor configured as a capacitor), coupled between node N2 and the voltage supply VDDIO. The value of capacitor C I is preferably selected to be greater than the capacitance between node N1 and VDDIO, which is primarily a function of the size (e.g., channel width and length) of transistor M3PC in output stage 402. Thus, capacitor C1 functions, at least in part, to compensate for the additional capacitance at node N1. Assuming transistor M3PC is a relatively standard size device (e.g., having a channel width of about 2 micrometers or less), capacitor C1 may be chosen to be about a few tens of femtofarads (e.g., about 30-50 femtofarads). In order to track process variations, capacitor C1 may comprise a PMOS device (not shown) which is sized larger than M3PC, thereby providing a larger coupling capacitance between node N2 and VDDIO compared to node N1.

Since node N2 is configured to have a higher coupling capacitance to VDDIO compared to node N1, node N2 will move high before node N1 as VDDIO ramps up. Node N2 being high turns off transistor M3PA and triggers the feedback circuit 404 by turning on transistor M3NFB, thereby pulling node N1 low. Latch circuit 406 maintains this state, since node N1 being low turns on transistor M3PB, thereby pulling node N2 up to VDDIO even harder. This is a stable circuit configuration, wherein node N1 being low forces the output signal Z to a high logic state.

Under normal operating conditions, the feedback circuit 404 has essentially no adverse effect on the voltage level translation operation of the voltage level translator circuit 400. By way of example only, when signal A is a logic high, transistor M3NA will turn on, thereby pulling node N I low and forcing output signal Z to a logic high. Node N1 being low turns on transistor M3PB, thereby pulling node N2 high. When signal A is a logic high, signal AN will be a logic low, thereby turning off transistor M3NB. Likewise, node N1 being low turns off transistor M3NFB in feedback circuit 304. With transistors M3NB and M3NFB being turned off, node N2 is allowed to be pulled high. Similarly, when signal A is low, transistor M3NA is turned off. Signal AN, being a complement of signal A, will be high, thereby turning on transistor M3NB and pulling node N2 low. Once node N2 falls about a threshold voltage below VDDIO, transistor M3PA turns on, thereby pulling node N1 high and turning off transistor M3PB. Node N1 being high turns on transistor M3NFB, thereby pulling node N2 low even harder. Thus in either case, feedback circuit 304 prevents node N1 from floating to an undefined level when the voltage supply VDDIO powers up before the core voltage supply VDDCORE, without consuming any significant DC current.

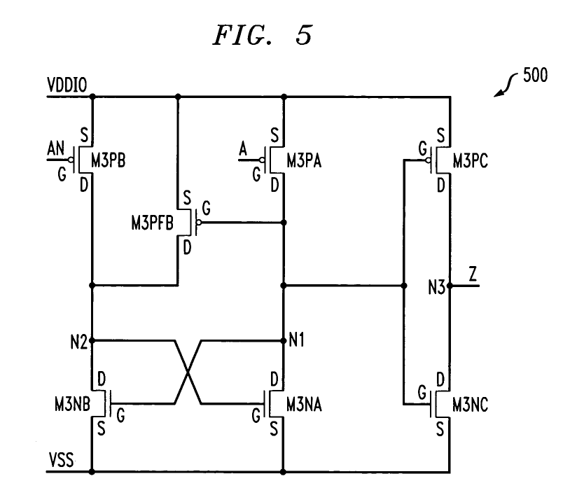

It is to be appreciated that the voltage level translation techniques of the present invention described herein may be used with alternative circuit configurations for translating among other voltage levels without consuming any significant DC power, as will be understood by those skilled in the art. For example, FIG. 5 illustrates an exemplary voltage level translator circuit 500, formed in accordance with an alternative embodiment of the invention. Voltage level translator circuit 500 is similar to the voltage level translator circuit 300 shown in FIG. 3, except that the circuit configurations are essentially flipped upside down from one another, and voltage level translator circuit 500 employs transistor devices having polarities opposite to the polarities of the transistor devices in voltage level translator circuit 300, as will be understood by those skilled in the art. Additionally, VDDIO and VDDCORE are preferably zero volts, VSS is preferably about −3.3 volts, and a negative lower core supply voltage VSSCORE is preferably about −1.0 volt, where VDDIO and VDDCORE are electrically isolated from one another, and VSS and VSSCORE are electrically isolated from one another.

At least a portion of the voltage level translator circuit of the present invention may be implemented in an integrated circuit. In forming integrated circuits, a plurality of identical die are typically fabricated in a repeated pattern on a surface of a semiconductor wafer. Each die includes a device described herein, and may include other structures or circuits. The individual die are cut or diced from the wafer, then packaged as an integrated circuit. One skilled in the art would know how to dice wafers and package die to produce integrated circuits. Integrated circuits so manufactured are considered part of this invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. A voltage level translator circuit for translating an input signal referenced to a first voltage supply to an output signal referenced to a second voltage supply, the circuit comprising:
an input stage for receiving the input signal;
a latch circuit having an input coupled to the input stage and having an output, the latch circuit being operative to store a signal at the output which is representative of a logical state of the input signal; and
a feedback circuit coupled between the input and the output of the latch circuit, the feedback circuit being operative to maintain a desired logic state of the voltage level translator circuit when the second voltage supply powers up before the first voltage supply.

2. The circuit of claim 1, wherein the input stage comprises first and second transistor devices, each transistor device including a source terminal, a drain terminal and a gate terminal, the source terminals being connected to a third voltage supply, the drain terminals being connected to the latch circuit, the gate terminal of the first transistor device receiving the input signal, and the gate terminal of the second transistor device receiving a logical inversion of the input signal.

3. The circuit of claim 1, wherein the latch circuit comprises first and second transistor devices, each transistor device including a source terminal, a drain terminal and a gate terminal, the source terminals being connected to the second voltage supply, the drain terminals being connected to the input stage, the gate terminal of the first transistor device being connected to the drain terminal of the second transistor device, and the gate terminal of the second transistor device being connected to the drain terminal of the first transistor device.

4. The circuit of claim 1, wherein the latch circuit comprises a differential latch configured such that the signal stored at the output of the latch is a complement of a signal at the input of the latch.

5. The circuit of claim 1, wherein the feedback circuit comprises a transistor device having a drain terminal connected to the input of the latch, a source terminal connected to a third voltage supply, and a gate terminal connected to the output of the latch.

6. The circuit of claim 1, wherein the feedback circuit comprises:
a transistor device having a drain terminal connected to the output of the latch, a source terminal connected to a third voltage supply, and a gate terminal connected to the input of the latch; and
a capacitance device coupled between the second voltage supply and the input of the latch.

7. The circuit of claim 1, wherein the feedback circuit comprises a capacitance device coupled between the second voltage supply and the input of the latch, a capacitance value of the capacitance device being greater than a capacitance between the output of the latch and the second voltage supply.

8. The circuit of claim 1, wherein the latch circuit comprises a pair of transistor devices connected in a cross-coupled arrangement.

9. The circuit of claim 1, wherein the feedback circuit is operative to maintain the desired logic state of the voltage level translator circuit when the second voltage supply powers up before the first voltage supply for a desired range of at least one of process, voltage and temperature variations.

10. The circuit of claim 1, wherein the feedback circuit is operative to maintain the desired logic state of the voltage level translator circuit when the second voltage supply powers up before the first voltage supply for a desired range of ramp rates of at least one of the first and second voltage supplies.

11. The circuit of claim 1, further comprising an output stage including an input coupled to the output of the latch circuit and an output for generating the output signal.

12. The circuit of claim 1, wherein a nominal voltage level of the first voltage supply is about 1.0 volt and a nominal voltage level of the second voltage supply is about 3.3 volts.

13. The circuit of claim 1, wherein the circuit is configured in a substantially static connection arrangement which consumes substantially no current when the input signal is quiescent.

14. An integrated circuit including at least one voltage level translator circuit for translating an input signal referenced to a first voltage supply to an output signal referenced to a second voltage supply, the at least one voltage level translator circuit comprising:
an input stage for receiving the input signal;
a latch circuit having an input coupled to the input stage and having an output, the latch circuit being operative to store a signal at the output which is representative of a logical state of the input signal; and
a feedback circuit coupled between the input and the output of the latch circuit, the feedback circuit being operative to maintain a desired logic state of the voltage level translator circuit when the second voltage supply powers up before the first voltage supply.

15. The integrated circuit of claim 14, wherein the input stage comprises first and second transistor devices, each transistor device including a source terminal, a drain terminal and a gate terminal, the source terminals being connected to a third voltage supply, the drain terminals being connected to the latch circuit, the gate terminal of the first transistor device receiving the input signal, and the gate terminal of the second transistor device receiving a logical inversion of the input signal.

16. The integrated circuit of claim 14, wherein the latch circuit comprises first and second transistor devices, each transistor device including a source terminal, a drain terminal and a gate terminal, the source terminals being connected to the second voltage supply, the drain terminals being connected to the input stage, the gate terminal of the first transistor device being connected to the drain terminal of the second transistor device, and the gate terminal of the second transistor device being connected to the drain terminal of the first transistor device.

17. The integrated circuit of claim 14, wherein the feedback circuit comprises a transistor device having a drain terminal connected to the input of the latch, a source terminal connected to a third voltage supply, and a gate terminal connected to the output of the latch.

18. The integrated circuit of claim 14, wherein the feedback circuit comprises:
a transistor device having a drain terminal connected to the output of the latch, a source terminal connected to a third voltage supply, and a gate terminal connected to the input of the latch; and
a capacitance device coupled between the second voltage supply and the input of the latch.

19. The integrated circuit of claim 14, wherein the feedback circuit comprises a capacitance device coupled between the second voltage supply and the input of the latch, a capacitance value of the capacitance device being greater than a capacitance between the output of the latch and the second voltage supply.

20. The integrated circuit of claim 14, wherein the feedback circuit is operative to maintain the desired logic state of the at least one voltage level translator circuit when the second voltage supply powers up before the first voltage supply for a desired range of at least one of process
